(19) United States
(12) Patent Application Publication
(10) Pub. No.: US 2026/0133480 A1
(43) Pub. Date: May 14, 2026

(54) PHOTOMASK MODULE AND PHOTOMASK PATTERN TRANSFER METHOD APPLYING THE SAME

(71) Applicant: United Microelectronics Corp., Hsinchu (TW)

(72) Inventors: Chun-Yi HSIEH, Tainan City (TW); Chun-Chi YU, Taipei City (TW); Bo-Jou LU, Tainan City (TW)

(21) Appl. No.: 19/006,309

(22) Filed: Dec. 31, 2024

(30) Foreign Application Priority Data
Nov. 11, 2024 (TW) 113143184

(51) Int. Cl. G03F 1/26; G03F 7/00; H01L 21/027

(52) U.S. Cl. CPC G03F 1/26; G03F 7/0035; H10P 76/2041

(57) ABSTRACT

A photomask module includes a first photomask and a second photomask. The first photomask includes a main circuit pattern. The second photomask includes a pad pattern, and the pad pattern includes a pad body pattern portion and an extension pattern portion. The extension pattern portion extends outward from the pad body pattern portion. When the first photomask and the second photomask overlap with each other, the extension pattern portion is at least partially surrounded by the main circuit pattern.

This application claims the benefit of Taiwan Application Serial No. 113143184 filed at Nov. 11, 2024 the subject matter of which is incorporated herein by reference.

### BACKGROUND

### Technical Field

The disclosure relates to an optical lithography device and the method for applying the same, and more particularly to a photomask module and photomask pattern transfer method for applying the same.

### Description of Background

With the development trend of semiconductor integrated circuit (IC) technology with increasing functional density (i.e., the number of interconnect devices per die area unit) and shrank geometric dimension (i.e., the smallest pitch or line used during the IC process), the circuit design and manufacture thereof have become more complex.

The lithography process is a process that transfers circuit design patterns from a photomask to a semiconductor wafer. A photoresist layer is coated on a surface of a wafer, and a photoresist pattern is then formed by performing expose and develop steps. Next, the photoresist pattern is transferred onto the wafer surface through an etching process, so as to form corresponding IC patterns in the wafer. The quality of the photoresist pattern will directly affect the quality of the final IC. How to ensure the mask pattern (circuit design patterns) perfectly transferred onto the photoresist layer coated on the wafer surface to form the IC patterns, during the lithography process, has become one of the critical technologies in semiconductor IC process technology.

Therefore, there is a need of providing a photomask module and photomask pattern transfer method for applying the same to obviate the drawbacks encountered from the prior art.

### SUMMARY

One aspect of the present disclosure is to provide a photomask module, wherein the photomask module includes a first photomask and a second photomask. The first photomask includes a main circuit pattern. The second photomask includes a pad pattern, and the pad pattern includes a pad body pattern portion and an extension pattern portion. The extension pattern portion extends outward from the pad body pattern portion. When the first photomask and the second photomask overlap with each other, the extension pattern portion is at least partially surrounded by the main circuit pattern.

Another aspect of the present disclosure is to provide a photomask pattern transfer method, wherein the method includes steps as follows: Firstly, a photomask module is provided, wherein the photomask module includes a first photomask and a second photomask. The first photomask includes a main circuit pattern. The second photomask includes a pad pattern, and the pad pattern includes a pad body pattern portion and an extension pattern portion. The extension pattern portion extends outward from the pad body pattern portion. When the first photomask and the second photomask overlap with each other, the extension pattern portion is at least partially surrounded by the main circuit pattern. Next, a first exposure and development process is performed to transfer the main circuit pattern into a positive photoresist through a negative tone development (NTD) technology. Then, a second exposure and development process is performed to transfer the pad pattern into the positive photoresist.

In accordance with the aforementioned embodiments of the present disclosure, a photomask module and photomask pattern transfer method for applying the same are provided. An original pattern provided by one single photomask is divided into a pad pattern and the main circuit pattern and respectively provided by two independent photomasks. Wherein, the pad pattern includes a pad body pattern portion and an extension pattern portion. The extension pattern portion extends outward from the pad body pattern portion. When these two divided photomasks overlap with each other, the pad pattern can be adjacent to the main circuit pattern; and at least a portion of the extension pattern portion extends into the main circuit pattern and is surrounded by the main circuit pattern.

Subsequently, different exposure and development processes using these two photomasks are performed to make the pad pattern and the main circuit pattern successively transferred into a positive photoresist layer coated on a semiconductor substrate by the NTD technology. By this approach, the transfer failure of the positive photoresist pattern occurred in the prior art lithography process using a single photomask, due the uneven distribution of the developer, can be prevented.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 is a diagram illustrating the composition pattern of a photomask module, according to one embodiment of the present disclosure;

FIG. 2 is a diagram illustrating the composition pattern of a photomask module, according to another embodiment of the present disclosure; and

FIGS. 3A and 3B are cross-sectional views illustrating a series processing structures for performing a photomask pattern transfer method according to one embodiment of the present disclosure.

### DETAILED DESCRIPTION

The embodiments as disclosed below provide a photomask module and photomask pattern transfer method for applying the same, which can prevent the transfer failure of the positive photoresist pattern occurred in the prior art lithography process using a single photomask, due the uneven distribution of the developer. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

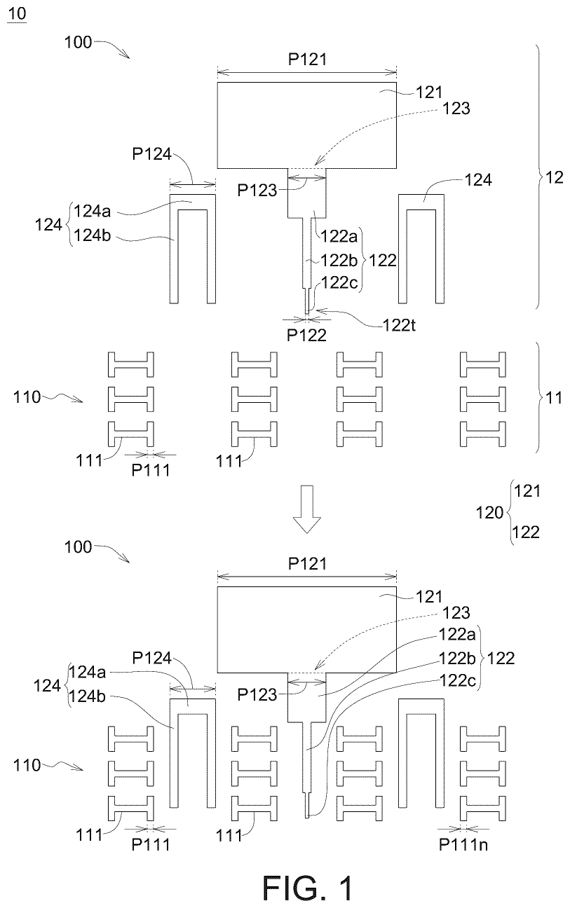

FIG. 1 is a diagram illustrating the composition pattern of a photomask module 10, according to one embodiment of the present disclosure. The mask module 10 includes a plurality of photomasks that are separated from each other. In other words, the photomask module 10 includes at least two photomasks (for example, the first photomask 11 and the second photomask 12) that are separated from each other.

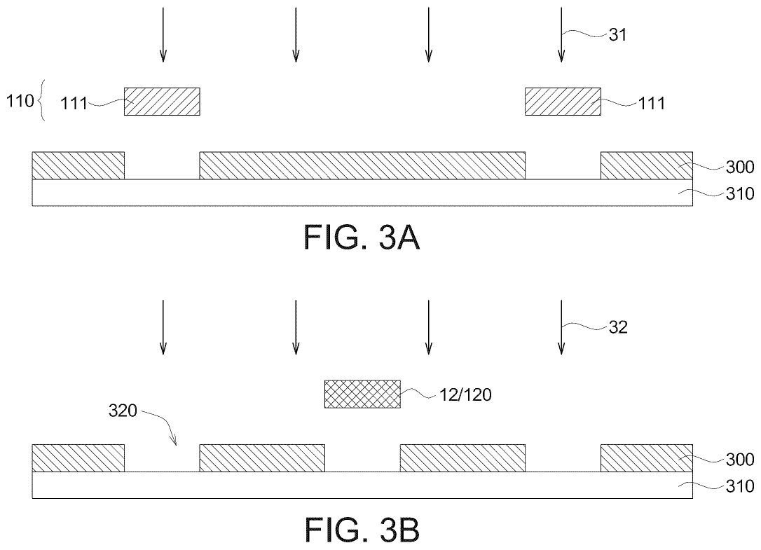

For example, in some embodiments of the present disclosure, the photomask module 10 may include two separate reticles/masks, and the circuit design pattern 100 (for example, the combination of the patterns respectively provided by the first photomask 11 and the second photomask 12) can be transferred into a photoresist layer (for example, a positive photoresist layer) 300 coated on the surface of the semiconductor substrate (for example, a semiconductor wafer) 310 by a plurality of lithography processes, so as to form a photoresist pattern 320 (please refer to FIG. 3A and FIG. 3B which will be described later).

For example, in the present embodiment, the photomask module 10 includes a first photomask 11 and a second photomask 12. The first photomask 11 includes a main circuit pattern 110. The second photomask 12 includes a pad pattern 120. The pad pattern 120 includes a pad body pattern portion 121 and an extension pattern portion 122. The extension pattern portion 122 extends outward from the pad body pattern portion 121. When the first photomask 11 and the second photomask 12 overlap with each other, at least a portion of the extension pattern portion 122 can be surrounded by the main circuit pattern 110.

In the present embodiment, each of the first photomask 11 and the second photomask 12 has a preset positioning point (not shown). And the above-mentioned overlapping the first photomask 11 and the second photomask 12 with each other means to overlapping the main circuit pattern 110 of the first photomask 11 and the pad pattern 120 of the second photomask 12 with each other based on the preset positioning points of the first photomask 11 and the second photomask 12.

In some other embodiments of the present disclosure, the first photomask 11 and the second photomask 12 respectively have a mask outer frame (not shown), and the dimensions of these two mask outer frames are the same. The above-mentioned overlapping the first photomask 11 and the second photomask 12 with each other alternatively means taking these two outer frames of the first photomask 11 and the second photomask 12 as a reference to overlapping the main circuit pattern 110 of the first photomask 11 and the pad pattern 120 of the second photomask 12 with each other.

In the present embodiment, the main circuit pattern 110 of the first photomask 11 includes a plurality of sub-circuit patterns 111 that are separated from each other. The plurality of sub-circuit patterns 111 may be different from each other or the same. The pad body pattern portion 121 of the second photomask 12 has a width P121 greater than the width P111 of each sub-circuit pattern 111; and the width P121 of the pad body pattern portion 121 is greater than the average width of the main circuit pattern 110. For example, in the present embodiment, the main circuit pattern 110 is composed of a plurality of sub-circuit patterns 111 with the same size. The average width of the main circuit pattern 110 is the width P111 of the sub-circuit pattern 111.

The pattern area of the main circuit pattern 110 of the first photomask 11 can be 90% to 60% of the pattern area of the circuit design pattern 100. The width P121 of the pad body pattern portion 121 of the second photomask 12 is substantially between 1 um and 60 um. The average width of the main circuit pattern 110 (the average of the summed width P111 of the plurality of sub-circuit pattern 111) is substantially between 0.35 um and 0.5 um. In the present embodiment, the width P121 of the pad body pattern portion 121 is substantially 48 um. The average width of the main circuit pattern 110 is substantially 0.42 um.

The width of the end portion 122t of the extension pattern portion 122 of the second photomask 12 that is farthest from the pad body pattern portion 121 can be regarded as the width P122 of the extension pattern portion 122. In some embodiments of the present disclosure, the width of the end portion 122t of the extension pattern portion 122 of the second photomask 12 that is farthest from the pad body pattern portion 121 (i.e., the width P122 of the extension pattern portion 122) is substantially between 0.03 um and 0.06 um. In the present embodiment, the width P122 of the extension pattern portion 122 is substantially 0.035 um. Of note that, in the embodiments of the present disclosure, the term “width” may refer to the local line width of the main circuit pattern 110 and the pad pattern 120 at the corresponding positions as described.

In some embodiments of the present disclosure, the width P122 of the extension pattern portion 122 of the second photomask 12 may gradually decrease as it moves away from the pad body pattern portion 121. The pad body pattern portion 121 is connected with the extension pattern portion 122 by a connection interface 123; and the ratio of the width P123 of the connection interface 123 and the width P122 of the extension pattern portion 122 may substantially range from 30/100 to 1/100. For example, in the present embodiment, the extension pattern portion 122 and the pad body pattern portion 121 are connected to each other through the connection interface 123, and the ratio of the width P123 of the connection interface 123 to the width P122 of the extension pattern portion 122 is substantially 24/100.

In addition, the extension pattern portion 122 may also include a plurality of sub-extension pattern portions 122a, 122b and 122c, which are connected to each other and are sequentially away from the pad body pattern portion 121. Wherein, the one of the sub-extension pattern portions 122a, 122b and 122c directly contact with the pad body pattern portion 121 (i.e., the sub-extension pattern portion 122a) has a first area, the one of the sub-extension pattern portions 122a, 122b and 122c farthest from the pad body pattern portion 121 (i.e., the sub-extension pattern portion 122c) has a second area, and the ratio of the first area to the second area is substantially between 1/1600 and 1/200.

In some embodiments of the present disclosure, the second photomask 12 further includes at least one auxiliary pattern 124, which is adjacent to the pad pattern 120 but separated from the pad pattern 120. When the first photomask 11 and the second photomask 12 overlap with each other, the auxiliary pattern 124 may be at least partially surrounded by the main circuit pattern 110 of the first photomask 11.

For example, in the present embodiment, the second photomask 12 further includes a plurality of auxiliary patterns 124 adjacent to the pad body pattern portion 121. The size and structure of the auxiliary patterns 124 can be the same or different; and the maximum width P124 of each auxiliary pattern 124 is smaller than the width P121 of the pad body pattern portion 121, but larger than the average width of the main circuit pattern 110 (as mentioned above, in the present embodiment, it is the width P111 of the sub-circuit pattern 111). Each of the auxiliary patterns 124 has a body portion 124a and an extension portion 124b. When the first photomask 11 and the second photomask 12 overlap with each other, the extension portion 124b can be disposed between the two adjacent sub-circuit patterns 111 of the main circuit pattern 110.

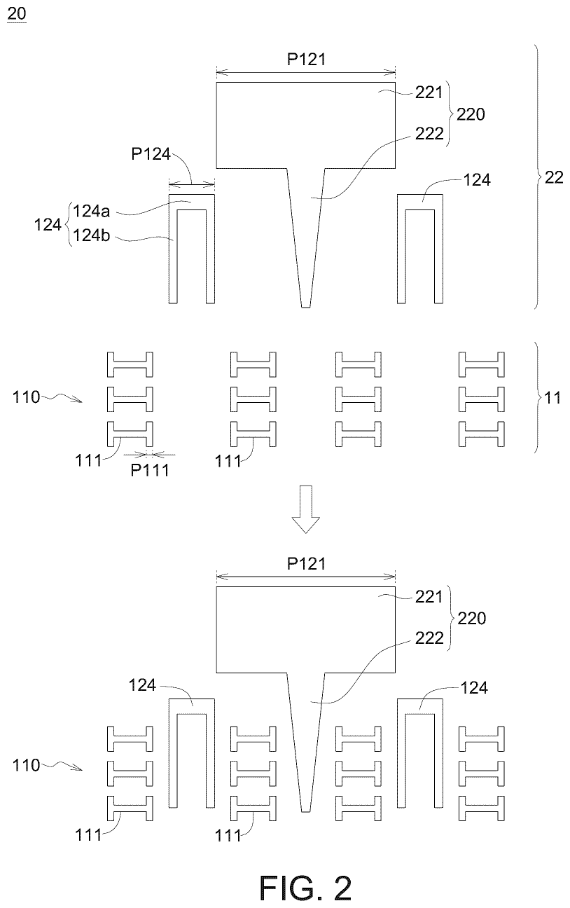

FIG. 2 is a diagram illustrating the composition pattern of a photomask module 20, according to another embodiment of the present disclosure. The mask module 20 (including the first photomask 11 and a second photomask 22) shown in FIG. 2 is similar to the mask module 10 shown in FIG. 1, and the difference there between lies in that the extension pattern portion 222 of the pad pattern 220 of the second photomask 22 in the photomask module 20 has smooth sides, and the width of the extension pattern portion 222 can gradually decrease as it moves away from the pad body pattern portion 221.

After the photomask module 10/20 is formed, the circuit design pattern 100 originally provided on the photomask module 10/20 can be transferred to the photoresist layer (e.g., the positive photoresist layer 300) coted on the surface of the semiconductor substrate (for example, a semiconductor wafer) 310 through a plurality of exposure and development techniques (steps). FIGS. 3A and 3B are cross-sectional views illustrating a series processing structures for performing a photomask pattern transfer method according to one embodiment of the present disclosure. The photomask pattern transfer method includes steps as follows:
Firstly, a first exposure and development process 31 is performed, using a light source with a preset wavelength (for example, an ultraviolet (UV), a deep ultraviolet (DUV) and/or an extreme ultraviolet (EUV), electron beam, ion beam, or X-ray, etc.,) to irradiate or radiate the first photomask 11 for changing the solubility of the photoresist in the photoresist layer 300 coated on the surface of the semiconductor substrate 310. The (exposed/unexposed) portion of the photoresist layer 300 with lower solubility is then dissolved and removed by a developer; thereby the main circuit pattern 110 of the first photomask 11 is transferred into the photoresist layer 300.

In some embodiments of the present disclosure, the first exposure and development process 31 may be a positive-photoresist-negative-development process, which is a special photolithography technology that uses a combination of positive photoresist and negative developer, usually used for specific processing needs. The positive-photoresist-negative-development process includes the following basic steps: Firstly, a positive-type photoresist is evenly coated (applied) on the substrate. Then, an exposure step is performed by irradiating UV light (or other light sources) onto the photoresist through a mask or photomask (for example, a reticle). At this time, the portions of the photoresist irritated by the light becomes can be soluble in the developer. Next, a negative development step is performed: by using a negative developer (usually an acidic solution) to dissolve and remove the unexposed portions of the photoresist, and to leave the exposed portions.

For example, the first exposure and development process 31 use DUV light with a wavelength between 365 nm and 193 nm to irradiate the first photomask 11 and the positive photoresist layer 300 coated on a substrate (e.g., the semiconductor substrate 310), so as to cause the portion of the positive photoresist layer 300 not covered by the main circuit pattern 110 to be cross-linked and solidified and insoluble in the negative developer due to the exposure, and to make the unexposed portions (the portions covered by the main circuit pattern 110) dissolved in the negative developer. Thereby the pattern opposite to the main circuit pattern 110 can be transferred onto the positive photoresist layer 300.

Thereinafter, a second exposure and development process 32 using the second photomask 12 as a mask (photomask/reticle) is performed; the same light source is used to irradiate the second photomask 12 and the positive photoresist layer 300. The pad pattern 120 of the second photomask 12 can be transferred onto the positive photoresist layer 300 by the negative development technology to form the photoresist pattern 320 as shown in FIG. 3B. Since the main circuit pattern 110 and the pad pattern 120 are respectively formed on the positive photoresist layer 300 through two exposure and development processes using different masks (photomask/reticle), thus using the negative developer to remove the portions of the positive photoresist layer 300 covered by the pad pattern 120 may not be affected by the other portions of the positive photoresist layer 300 covered by the main circuit pattern 110 (which has been removed at this time). Thereby, the transfer failure of the pad pattern 120 caused by the uneven distribution of the developer can be prevented.

Subsequently, an etching process (not shown) using the positive photoresist layer 300 with the photoresist pattern 320 as a mask is performed to remove a portion of the semiconductor material of the semiconductor substrate (e.g., silicon material of the silicon wafer), so as to transfer the photoresist pattern 320 onto the surface of the silicon wafer (the semiconductor substrate 310). Thereby, an integrated circuit pattern corresponding to the circuit design pattern 100 provided on the mask module 10 can be formed on the surface of the silicon wafer (the semiconductor substrate 310).

In accordance with the aforementioned embodiments of the present disclosure, a photomask module and photomask pattern transfer method for applying the same are provided. An original pattern provided by one single photomask is divided into a pad pattern and the main circuit pattern and respectively provided by two independent photomasks. Wherein, the pad pattern includes a pad body pattern portion and an extension pattern portion. The extension pattern portion extends outward from the pad body pattern portion. When these two divided photomasks overlap with each other, the pad pattern can be adjacent to the main circuit pattern; and at least a portion of the extension pattern portion extends into the main circuit pattern and is surrounded by the main circuit pattern.

Subsequently, different exposure and development processes using these two photomasks are performed to make the pad pattern and the main circuit pattern successively transferred into a positive photoresist layer coated on a semiconductor substrate by the NTD technology. By this approach, the transfer failure of the positive photoresist pattern occurred in the prior art lithography process using a single photomask, due the uneven distribution of the developer, can be prevented.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A photomask module, comprising:
a first photomask, comprising a main circuit pattern; and
a second photomask, comprising a pad pattern, wherein the pad pattern comprises a pad body pattern portion and an extension pattern portion; the extension pattern portion extends outward from the pad body pattern portion; when the first photomask and the second photomask overlap with each other, the extension pattern portion is at least partially surrounded by the main circuit pattern.

2. The photomask module according to claim 1, wherein the extension pattern portion has a dimension gradually decreased as it moves away from the pad body pattern portion.

3. The photomask module according to claim 2, wherein the extension pattern portion has a connection interface connecting to the pad body pattern portion and an end portion that is farthest from the connection interface; the connection interface has a first width; the end portion has a second width; and a ratio of the second width to the first width substantially ranges from 30/100 to 1/100.

4. The photomask module according to claim 2, wherein the extension pattern comprises a plurality of sub-extension pattern portions, which are connected to each other and are sequentially away from the pad body pattern portion; one of the sub-extension pattern portions directly contact with the pad body pattern portion has a first area, another one of the sub-extension pattern portions farthest from the pad body pattern portion has a second area; and a ratio of the first area to the second area is substantially between 1/1600 and 1/200.

5. The photomask module according to claim 1, wherein the second photomask further comprises an auxiliary pattern adjacent to the pad pattern but separated from the pad pattern; when the first photomask and the second photomask overlap with each other, the auxiliary pattern is at least partially surrounded by the main circuit pattern.

6. A photomask pattern transfer method, comprising:
providing a photomask module, comprising:
a first photomask, comprising a main circuit pattern; and
a second photomask, comprising a pad pattern, wherein the pad pattern comprises a pad body pattern portion and an extension pattern portion; the extension pattern portion extends outward from the pad body pattern portion; when the first photomask and the second photomask overlap with each other, the extension pattern portion is at least partially surrounded by the main circuit pattern;
performing a first exposure and development process to transfer the main circuit pattern into a positive photoresist through a negative tone development (NTD) technology; and
performing a second exposure and development process to transfer the pad pattern into the positive photoresist.

7. The method according to claim 6, wherein the extension pattern portion has a dimension gradually decreased as it moves away from the pad body pattern portion.

8. The method according to claim 7, wherein the extension pattern portion has a connection interface connecting to the pad body pattern portion and an end portion that is farthest from the connection interface; the connection interface has a first width; the end portion has a second width; and a ratio of the second width to the first width substantially ranges from 30/100 to 1/100.

9. The method according to claim 8, wherein the extension pattern comprises a plurality of sub-extension pattern portions, which are connected to each other and are sequentially away from the pad body pattern portion; one of the sub-extension pattern portions directly contact with the pad body pattern portion has a first area, another one of the sub-extension pattern portions farthest from the pad body pattern portion has a second area; and a ratio of the first area to the second area is substantially between 1/1600 and 1/200.

10. The method according to claim 6, wherein the second photomask further comprises an auxiliary pattern adjacent to the pad pattern but separated from the pad pattern; when the first photomask and the second photomask overlap with each other, the auxiliary pattern is at least partially surrounded by the main circuit pattern.
